(19) United States
(12) Patent Application Publication
(10) Pub. No.: US 2024/0186251 A1
(43) Pub. Date: Jun. 6, 2024

(54) SYMMETRIC DUMMY BRIDGE DESIGN FOR FLI ALIGNMENT IMPROVEMENT

(71) Applicant: Intel Corporation, Santa Clara, CA (US)

(72) Inventors: Minglu LIU, Chandler, AZ (US); YANG WU, Chandler, AZ (US); Yuting WANG, Chandler, AZ (US); Lawrence ROSS, Chandler, AZ (US); Mine KAYA, Scottsdale, AZ (US); Gang DUAN, Chandler, AZ (US); Edvin CETEGEN, Chandler, AZ (US); Alexander AGUINAGA, Phoenix, AZ (US)

(21) Appl. No.: 18/075,360

(22) Filed: Dec. 5, 2022

(51) Int. Cl. H01L 23/538; H01L 23/00; H01L 23/13; H01L 25/065

(52) U.S. Cl. CPC H01L 23/5381; H01L 23/13; H01L 23/5385; H01L 23/5386; H01L 24/16; H01L 25/0655; H01L 24/81; H01L 2224/16227; H01L 2224/81203; H01L 2924/351

(57) ABSTRACT

Embodiments disclosed herein include package architectures. In an embodiment, the package architecture comprises a package substrate, a first bridge in the package substrate, where the first bridge includes conductive routing, and a second bridge in the package substrate. In an embodiment, the package architecture further comprises a third bridge in the package substrate, where the second bridge and the third bridge are positioned symmetrically about the first bridge.

### TECHNICAL FIELD

Embodiments of the present disclosure relate to electronic packages, and more particularly to packaging architectures with embedded bridge architectures that include dummy bridges in order to improve first level interconnect (FLI) alignment.

### BACKGROUND

In advanced packaging architectures, smaller dies (also referred to as chiplets, tiles, etc.) are communicatively coupled together using one or more bridge dies. The bridge dies may be embedded in the package substrate between pairs of dies. The bridge dies include high density routing in order to couple together the overlying dies. As more bridge dies are integrated into the electronic package, alignment issues become more prevalent.

One specific misalignment mode is referred to as die edge misalignment (DEM). DEM is seen on multiple bridge die packages at first level interconnects (FLIs) after thermocompression bonding (TCB). This DEM is found only on certain areas (e.g., edges) of the die. Further, such misalignment modes are typically not symmetrical with respect to the die center. As such, it can be deduced that the misalignment is not attributable to tool placement offset or inaccurate bump compensation.

Generally, DEM is not well understood. However, some investigation has shown that edge misalignment and direction of misalignment correlates well with bridge die layout around the overlying dies. Without being tied to a specific understanding of the cause of DEM, it has been deduced that asymmetrical substrate thermal expansion during fast heating/cooling cycles during TCB may contribute to DEM problems.

### BRIEF DESCRIPTION OF THE DRAWINGS

FIG. 1 is a cross-sectional illustration of an electronic package that includes an embedded bridge die for coupling together a pair of overlying dies, and the overlying dies include die edge misalignment (DEM).

FIG. 2A is a plan view illustration of an electronic package that includes an embedded bridge between overlying dies, where asymmetric bridge layout results in DEM, in accordance with an embodiment.

FIG. 2B is a plan view illustration of an electronic package that includes an embedded bridge and a pair of dummy bridges in order to improve DEM, in accordance with an embodiment.

FIG. 2C is a cross-sectional illustration of the electronic package in FIG. 2B along line C-C′, in accordance with an embodiment.

FIG. 2D is a cross-sectional illustration of an electronic package that includes a bridge in a mold layer and a pair of dummy bridges in order to improve DEM, in accordance with an embodiment

FIG. 3A is a plan view illustration of an electronic package with a plurality of embedded bridges and a plurality of overlying dies that suffer from DEM, in accordance with an embodiment.

FIG. 3B is a plan view illustration of an electronic package that includes dummy bridges in order to provide a more symmetric bridge layout in order to mitigate DEM, in accordance with an embodiment.

FIG. 4A is a plan view illustration of an electronic package with a plurality of embedded bridges and a plurality of overlying dies where each overlying die is coupled to more than one other overlying die, in accordance with an embodiment.

FIG. 4B is a plan view illustration of an electronic package that includes dummy bridges in order to provide a more symmetric bridge layout in order to mitigate DEM, in accordance with an embodiment.

FIG. 5 is a cross-sectional illustration of an electronic system that includes a package substrate with an embedded bridge and a pair of dummy bridges outside of a footprint of the overlying dies, in accordance with an embodiment.

FIG. 6 is a schematic of a computing device built in accordance with an embodiment.

### EMBODIMENTS OF THE PRESENT DISCLOSURE

Described herein are packaging architectures with embedded bridge architectures that include dummy bridges in order to improve first level interconnect (FLI) alignment, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, advanced packaging architectures are moving towards the use of one or more bridge dies in order to communicatively couple together overlying dies. The overlying dies may be compute dies that are processed at an advanced node. In order to keep yields of the overlying dies high, smaller (in area) dies are used. Benefits in computing power can be leveraged by coupling together multiple smaller dies. Generally, the bridge dies lie at least partially below a footprint of two overlying dies. Interconnects (e.g., first level interconnects (FLIs)) couple the overlying dies to the underlying bridge die. High density routing on the bridge die provides communicative coupling between the overlying dies.

However, the inclusion of one or more bridge dies has resulted in the problem of die edge misalignment (DEM). The DEM is a phenomenon that cannot be attributable to tool offset or inaccurate bump compensation. While not being tied to a particular mechanism, it is presumed that DEM can be at least partially attributable to non-uniformity and material asymmetry in the package substrate due to the presence of one or more embedded bridge substrates. Generally, it is presumed that differences in thermal expansion during the temperature cycling of thermocompression bonding (TCB) may be a contributing factor to DEM.

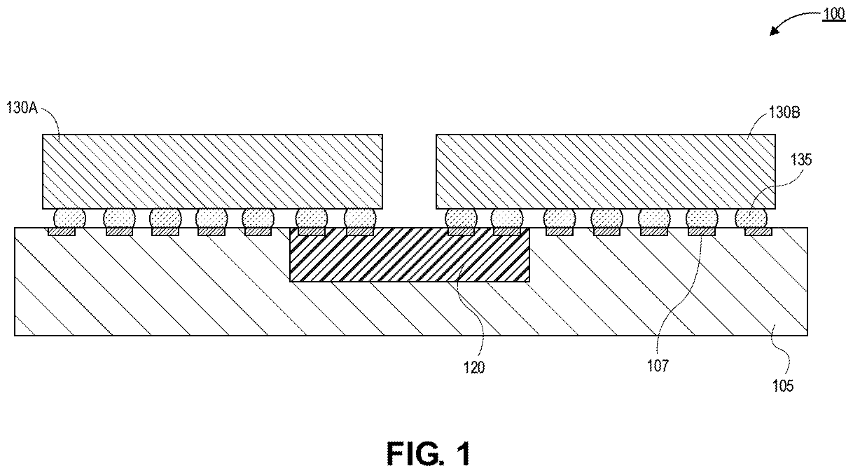

An example of DEM is shown in FIG. 1. FIG. 1 shows an electronic package 100. The electronic package 100 may include a package substrate 105. The package substrate 105 may be an organic material, such as a plurality of layers of buildup film. In some instances, the package substrate 105 may also include a core (not shown). Though, coreless architectures may also be used in some instances. Conductive routing (not shown) may be provided through the package substrate 105 in order to couple overlying dies 130A and 130B to a board (not shown). The conductive routing may include vias, pads, traces, and the like.

In some instances an embedded bridge 120 may be provided in the package substrate 105. The embedded bridge 120 may include high density conductive routing in order to communicatively couple the first die 130A to the second die 130B. The first die 130A and the second die 130B may be coupled to the package substrate 105 and the bridge 120 by FLIs 135. As illustrated in FIG. 1, the outer FLIs 135 are misaligned with the underlying pads 107. As noted above, the misalignment may be characterized as DEM and be caused by the non-uniform material composition of the package substrate. That is, the presence of the bridge 120 may result in misalignment towards the edges of the package substrate 100.

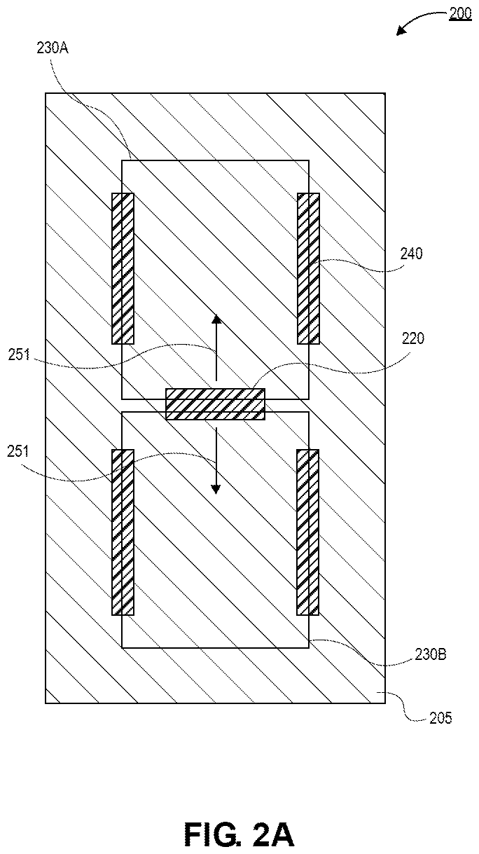

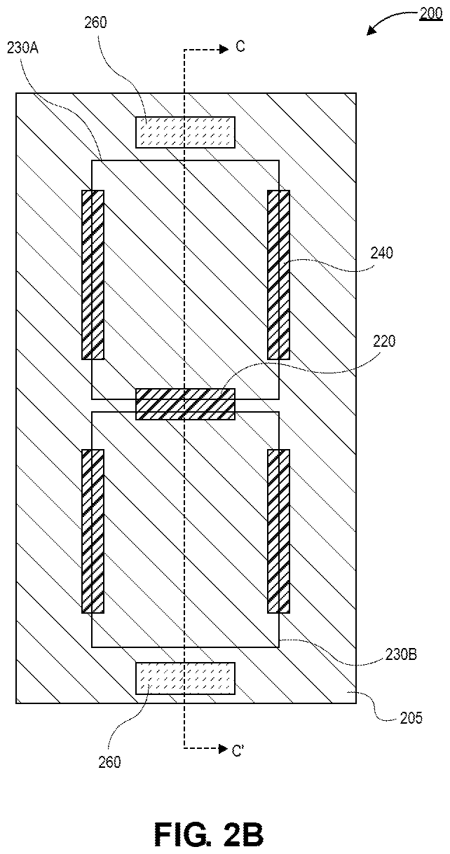

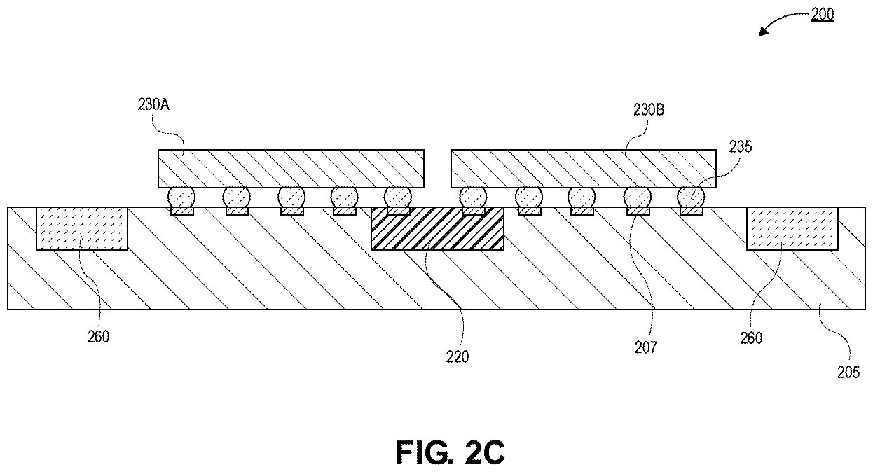

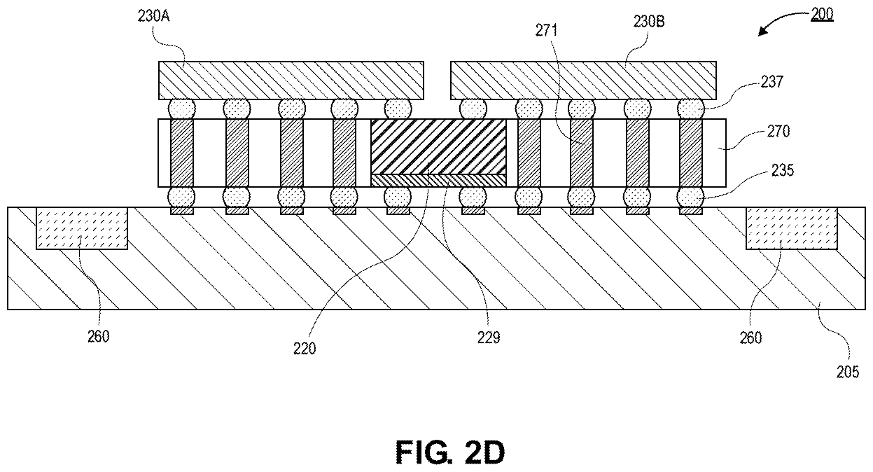

Referring now to FIG. 2A, a plan view illustration of an electronic package 200 is shown, in accordance with an embodiment. The electronic package 200 may include a package substrate 205. The package substrate 205 may include an organic material, such as a buildup film. In some instances, the package substrate 205 may include a core, such as a glass core or an organic core. One or more bridges 220 may be embedded in the package substrate 205. In the particular embodiment shown in FIG. 2A, the bridge 220 is provided between a first die 230A and a second die 230B. The first die 230A and the second die 230B are shown without shading in order to indicate that the first die 230A and the second die 230B are provided above the package substrate 205.

In an embodiment, the bridge 220 is at least partially below a footprint of both the first die 230A and the second die 230B. More generally, the bridge 220 may be provided at a center of the package substrate 205 (as viewed in the plan view of FIG. 2A). Additional bridges 240 or other components may be provided around perimeters of the first die 230A and the second die 230B. The additional bridges 240 may be provided along edges of the first die 230A and the second die 230B. The additional bridges 240 may be provided under the footprint of only one of the first die 230A and the second die 230B.

In an embodiment, the bridge 220 may include high density routing in order to communicatively couple the first die 230A to the second die 230B. While two dies 230A and 230B are shown in FIG. 2A, it is to be appreciated that additional dies 230 may also be included in some embodiments. In such instances each of the additional dies 230 may be communicatively coupled to a second die 230 by a single bridge 220. Examples of multiple die 230 and bridge 220 architectures are provided in greater detail below. In an embodiment, the bridge 220 is a material that is different than the material of the package substrate 205. The bridge 220 may include silicon or another semiconductor material. In other embodiments, the bridge 220 may comprise glass.

As shown in FIG. 2A, DEM may occur in the direction indicated by the arrows 251. That is, the misalignment may be oriented in a direction away from (i.e., up and down in FIG. 2A) the bridge 220. This is because the thermal expansion at the center of the package substrate 205 is different than the thermal expansion towards the edges of the package substrate 205. For example, the top and bottom edges of the package substrate 205 may expand more than the center of the package substrate 205 during rapid thermal cycling (e.g., during TCB processes). This can cause FLIs between the dies 230A/230B and the package substrate 205 to be misaligned.

Accordingly, embodiments disclosed herein include architectures that more symmetrically balance the thermal expansion of the electronic package 200. Referring now to FIG. 2B, a plan view illustration of an electronic package 200 with a more symmetrically balanced thermal expansion is shown, in accordance with an embodiment. In an embodiment, the electronic package 200 in FIG. 2B may be substantially similar to the electronic package 200 shown in FIG. 2A, with the exception of the addition of dummy bridges 260. For example, dummy bridges 260 are provided along the top edge and the bottom edge of the package substrate 205.

In an embodiment, the dummy bridges 260 may be substantially similar to the bridge 220, with the exception of the presence of conductive routing. For example, the dummy bridges 260 may not include any conductive routing. Instead, the dummy bridges 260 may be a monolithic body of material. In an embodiment, the material of the dummy bridges 260 may be the same material as the bridge 220. For example, when the bridge 220 comprises silicon, the dummy bridges 260 may also comprise silicon. Similarly, if the bridge 220 comprises glass, then the dummy bridges 260 may also comprise glass. Though, in some embodiments the dummy bridges 260 may be a different material than the bridge 220.

In an embodiment, the bridge 220 may have one or more dimensions that are matched with the dummy bridges 260. For example, in FIG. 2B, the dummy bridges 260 have the same width and length as the bridge 220. In other embodiments, one of the width or the length of the dummy bridges 260 may be matched with the corresponding width or length of the bridge 220. In an embodiment, a centerline of the dummy bridges 260 may be substantially coincident with a centerline of the bridge 220. For example, the dashed line C-C′ is provided over both the centerline of the bridge 220 and the centerlines of the dummy bridges 260.

In an embodiment, the dummy bridges 260 are placed in locations that mitigate the non-uniform thermal expansion of the package substrate 205. For example, as indicated in FIG. 2A, the direction of DEM is towards the top and bottom edges of the package substrate 205. As such, the dummy bridges 260 are positioned proximate to the top and bottom edges of the package substrate 205. At these locations, the thermal expansion is matched with that of the center of the package substrate 205 proximate to the bridge 220.

In some embodiments, the dummy bridges 260 are provided entirely outside a footprint of both the first die 230A and the second die 230B. Moving the dummy bridges 260 outside of the footprint of the dies 230A/230B allows for more die area to be used for functioning circuitry. However, in some embodiments, the dummy bridges 260 may be at least partially within a footprint of one or both of the first die 230A and the second die 230B. In an embodiment, the distance between the bridge 220 and the dummy bridges 260 may be substantially uniform. For example, a distance from the bridge 220 to the top dummy bridge 260 may be substantially equal to a distance from the bridge 220 to the bottom dummy bridge 260. In some instances, the positioning of the dummy bridges 260 may be referred to as being symmetric about the bridge die 220. However, in other embodiments, the distances between the bridge 220 and the dummy bridges 260 may be non-uniform. For example, when the dimensions of the first die 230A and the second die 230B are different, the distances between the dummy bridges 260 and the bridge 220 may be non-uniform.

Referring now to FIG. 2C, a cross-sectional illustration of the electronic package 200 in FIG. 2B along line C-C′ is shown, in accordance with an embodiment. As shown, the bridge 220 and the dummy bridges 260 are embedded in the package substrate 205. The overlying dies 230A and 230B may be electrically coupled to the package substrate 205 and the bridge 220 using FLIs 235. The FLIs 235 may be provided over pads 207 on the package substrate 205 and the bridge 220. As shown, the FLIs 235 are properly aligned with the pads 207. The improvement in alignment can be at least partially attributable to the presence of the dummy bridges 260 symmetrically positioned about the bridge 220.

As shown, the dummy bridges 260 may have a thickness that is substantially equal to the thickness of the bridge 220. In other embodiments, the bridge 220 may be thicker or thinner than the dummy bridges 260. In the illustrated embodiment, the width of the dummy bridges 260 is shown as being different than the width of the bridge 220. Though, in some embodiments, the width of the dummy bridges 260 may be substantially equal to the width of the bridge 220, as shown in FIG. 2B. Furthermore, while shown as having different shadings, the dummy bridges 260 may be the same material as the bridge 220.

In an embodiment, the dies 230A and 230B may be communicatively coupled to each other through conductive routing on the bridge 220. The conductive routing on the bridge 220 is omitted for simplicity. In an embodiment, the dies 230A and 230B may both be compute dies, such as processors, graphics processors, systems on a chip (SoC), ASICs, or the like. One or both of the dies 230A and 230B may also be memory dies in some instances. In a particular embodiment, the die 230A may be substantially similar to the die 230B. Though, embodiments may also include dies 230A and 230B that are different from each other.

Referring now to FIG. 2D, a cross-sectional illustration of an electronic package 200 is shown, in accordance with an additional embodiment. The electronic package 200 in FIG. 2D is substantially similar to the electronic package 200 in FIG. 2C, with the exception of the placement of the bridge 220. Instead of being in the package substrate 205, the bridge 220 is provided in an overlying mold layer 270. Through mold vias 271 may provide electrical connection between FLIs 235 and FLIs 237. The bridge 220 may be provided over a base or adhesive 229.

In an embodiment, the dummy bridges 260 may be provided in the package substrate 205. That is, the bridge 220 and the dummy bridges 260 may be provided in different substrates. However, in other embodiments, the dummy bridges 260 may also be provided in the overlying mold layer 270.

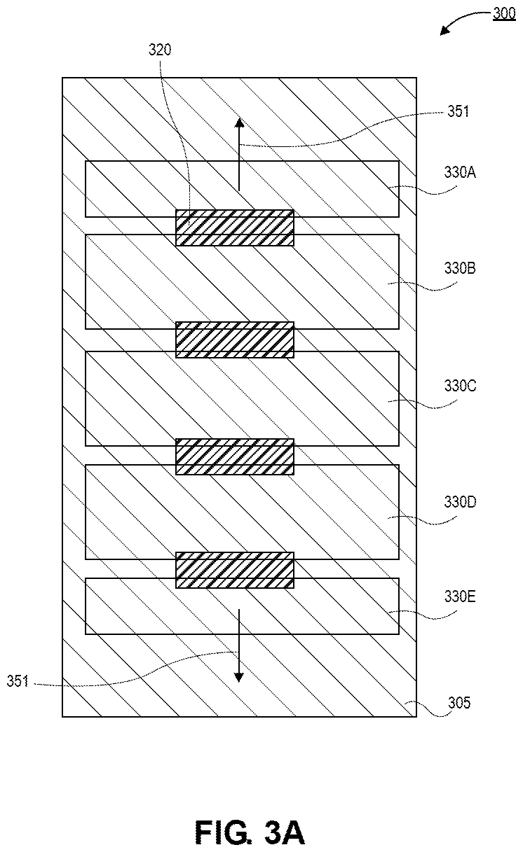

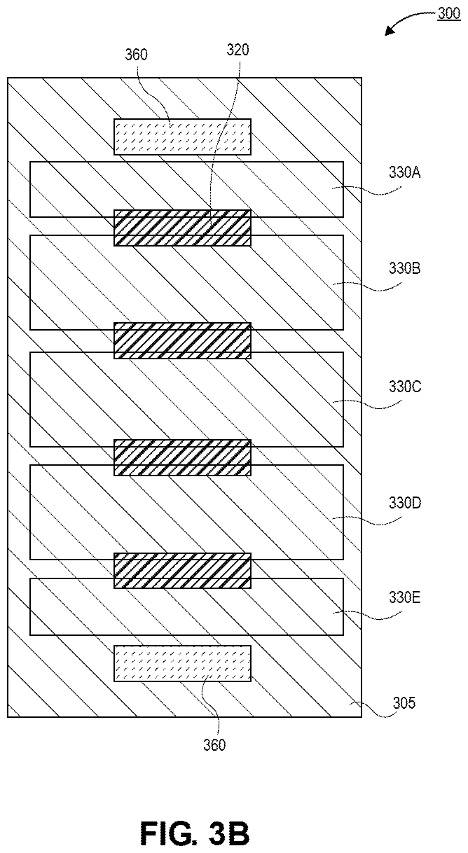

Referring now to FIG. 3A, a plan view illustration of an electronic package 300 is shown, in accordance with an embodiment. The electronic package 300 may include a package substrate 305. The package substrate 305 may include an organic material, such as a buildup film. In some instances, the package substrate 305 may include a core, such as a glass core or an organic core. A plurality of bridges 320 may be embedded in the package substrate 305. In the particular embodiment shown in FIG. 3A, a bridge 320 is provided between each pair of dies 330. For example, a bridge 320 is provided at the interface between the first die 330A and the second die 330B. While a single bridge 320 is provided between each pair of dies 330, it is to be appreciated that one or more bridges 320 may be provided between each pair of dies 330. In an embodiment, each bridge 320 is at least partially below a footprint of two dies 330. The dies 330A-330E are shown without shading in order to indicate that the dies 330A-330E are provided above the package substrate 305.

In an embodiment, the bridges 320 may include high density routing in order to communicatively couple pairs of dies 330 together. While five dies 330A-330E are shown in FIG. 3A, it is to be appreciated that any number of dies 330 may be included in some embodiments. In an embodiment, the bridges 320 are a material that is different than the material of the package substrate 305. The bridges 320 may include silicon or another semiconductor material. In other embodiments, the bridges 320 may comprise glass.

As shown in FIG. 3A, DEM may occur in the direction indicated by the arrows 351. That is, the misalignment may be oriented in a direction away from (i.e., up and down in FIG. 3A) the bridges 320. This is because the thermal expansion at the center of the package substrate 305 is different than the thermal expansion towards the edges of the package substrate 305. For example, the top and bottom edges of the package substrate 305 may expand more than the center of the package substrate 305 during rapid thermal cycling (e.g., during TCB processes). This can cause FLIs between the dies 330A-330E and the package substrate 305 to be misaligned.

Accordingly, embodiments disclosed herein include architectures that more symmetrically balance the thermal expansion of the electronic package 300. Referring now to FIG. 3B, a plan view illustration of an electronic package 300 with more symmetrically balanced thermal expansion is shown, in accordance with an embodiment. In an embodiment, the electronic package 300 in FIG. 3B may be substantially similar to the electronic package 300 shown in FIG. 3A, with the exception of the addition of dummy bridges 360. For example, dummy bridges 360 are provided along the top edge and the bottom edge of the package substrate 305.

In an embodiment, the dummy bridges 360 may be substantially similar to the bridges 320, with the exception of the presence of conductive routing. For example, the dummy bridges 360 may not include any conductive routing. Instead, the dummy bridges 360 may be a monolithic body of material. In an embodiment, the material of the dummy bridges 360 may be the same material as the bridges 320. For example, when the bridge 320 comprises silicon, the dummy bridges 360 may also comprise silicon. Similarly, if the bridges 320 comprise glass, then the dummy bridges 360 may also comprise glass. Though, in some embodiments the dummy bridges 360 may be a different material than the bridges 320.

In an embodiment, the bridges 320 may have one or more dimensions that are matched with the dummy bridges 360. For example, in FIG. 3B, the dummy bridges 360 have the same width and length as the bridges 320. In other embodiments, one of the width or the length of the dummy bridges 360 may be matched with the corresponding width or length of the bridges 320. Further, the number of dummy bridges 360 in a row may be matched with the number of bridges 320 in a row. For example, each row of dummy bridges 360 includes a single dummy bridge 360, and each row of bridges 320 includes a single bridge 320.

In an embodiment, the dummy bridges 360 are placed in locations that mitigate the non-uniform thermal expansion of the package substrate 305. For example, as indicated in FIG. 3A, the direction of DEM is towards the top and bottom edges of the package substrate 305. As such, the dummy bridges 360 are positioned proximate to the top and bottom edges of the package substrate 305. At these locations, the thermal expansion is matched with that of the center of the package substrate 305 proximate to the bridges 320.

In some embodiments, the dummy bridges 360 are provided entirely outside a footprint of the dies 330A-330E. Moving the dummy bridges 360 outside of the footprint of the dies 330A-330E allows for more die area to be used for functioning circuitry. However, in some embodiments, the dummy bridges 360 may be at least partially within a footprint of one dies 330A-330E. In an embodiment, the distance between the bridges 320 and the dummy bridges 360 may be substantially uniform. For example, a distance from the bridge 320 between the dies 330A and 330B to the top dummy bridge 360 may be substantially equal to a distance from the bridge 320 between dies 330D and 330E to the bottom dummy bridge 360. In some instances, the positioning of the dummy bridges 360 may be referred to as being symmetric about the bridge dies 320. However, in other embodiments, the distances between the bridge 320 and the dummy bridges 360 may be non-uniform.

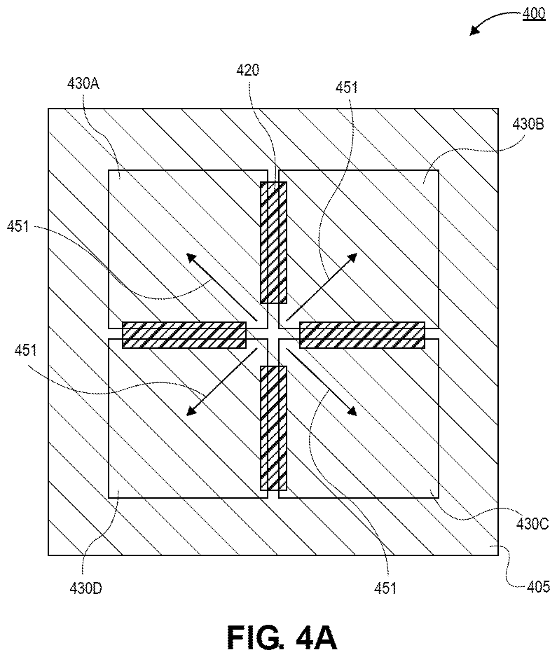

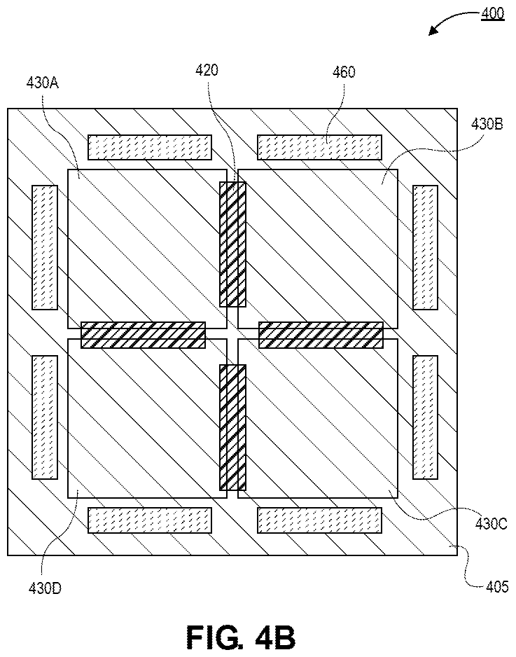

Referring now to FIG. 4A, a plan view illustration of an electronic package 400 is shown, in accordance with an embodiment. The electronic package 400 may include a package substrate 405. The package substrate 405 may include an organic material, such as a buildup film. In some instances, the package substrate 405 may include a core, such as a glass core or an organic core. A plurality of bridges 420 may be embedded in the package substrate 405. In the particular embodiment shown in FIG. 4A, a pair of bridges 420 is provided between each pair of dies 430. For example, a single bridge 420 is provided at the interface between the first die 430A and the second die 430B. While a single bridge 420 is provided between each pair of dies 430, it is to be appreciated that one or more bridges 420 may be provided between each pair of dies 430. In an embodiment, each bridge 420 is at least partially below a footprint of two dies 430. The dies 430A-430D are shown without shading in order to indicate that the dies 430A-430D are provided above the package substrate 405.

In an embodiment, the bridges 420 may include high density routing in order to communicatively couple pairs of dies 430 together. While four dies 430A-430D are shown in FIG. 4A, it is to be appreciated that any number of dies 430 may be included in some embodiments. In an embodiment, the bridges 420 are a material that is different than the material of the package substrate 405. The bridges 420 may include silicon or another semiconductor material. In other embodiments, the bridges 420 may comprise glass.

As shown in FIG. 4A, DEM may occur in the direction indicated by the arrows 451. That is, the misalignment may be oriented in a direction away from a center of the package substrate 405. Due to the square layout of the dies 430A-430D and the corresponding position of the bridges 420, the arrows point out towards the corners of the package substrate 405.

Accordingly, embodiments disclosed herein include architectures that more symmetrically balance the thermal expansion of the electronic package 400. Referring now to FIG. 4B, a plan view illustration of an electronic package 400 with more symmetrically balanced thermal expansion is shown, in accordance with an embodiment. In an embodiment, the electronic package 400 in FIG. 4B may be substantially similar to the electronic package 400 shown in FIG. 4A, with the exception of the addition of dummy bridges 460. For example, dummy bridges 460 are provided along a pair of outer edges for each of the dies 430A-430D. As such, dummy bridges 460 may be provided along a first edge, a second edge, a third edge, and a fourth edge of the package substrate 405. More particularly, a pair of dummy bridges 460 are provided along each edge of the package substrate 405.

In an embodiment, the dummy bridges 460 may be substantially similar to the bridges 420, with the exception of the presence of conductive routing. For example, the dummy bridges 460 may not include any conductive routing. Instead, the dummy bridges 460 may be a monolithic body of material. In an embodiment, the material of the dummy bridges 460 may be the same material as the bridges 420. For example, when the bridge 420 comprises silicon, the dummy bridges 460 may also comprise silicon. Similarly, if the bridges 420 comprise glass, then the dummy bridges 460 may also comprise glass. Though, in some embodiments the dummy bridges 460 may be a different material than the bridges 420.

In an embodiment, the bridges 420 may have one or more dimensions that are matched with the dummy bridges 460. For example, in FIG. 4B, the dummy bridges 460 have the same width as the bridges 420. In other embodiments, both the width and the length of the dummy bridges 460 may be matched with the width and the length of the bridges 420.

In an embodiment, the dummy bridges 460 are placed in locations that mitigate the non-uniform thermal expansion of the package substrate 405. For example, as indicated in FIG. 4A, the direction of DEM is towards the corners of the package substrate 405. As such, the dummy bridges 460 are positioned proximate to each edge of the package substrate 405 in order to balance the DEM. At these corner locations, the thermal expansion is matched with that of the center of the package substrate 405.

In some embodiments, the dummy bridges 460 are provided entirely outside a footprint of the dies 430A-430D. Moving the dummy bridges 460 outside of the footprint of the dies 430A-430D allows for more die area to be used for functioning circuitry. However, in some embodiments, the dummy bridges 460 may be at least partially within a footprint of one dies 430A-430D.

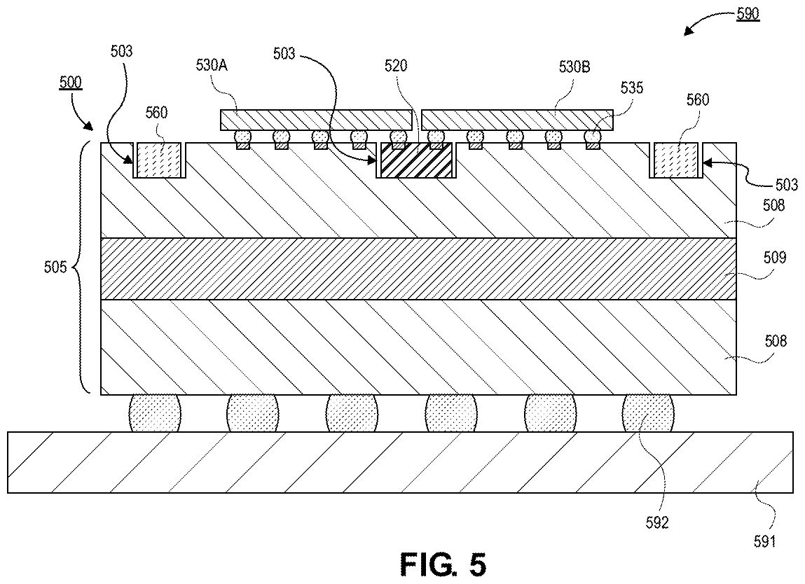

Referring now to FIG. 5, a cross-sectional illustration of an electronic system 590 is shown, in accordance with an embodiment. In an embodiment, the electronic system 590 may comprise a board 591, such as a PCB or the like. In an embodiment, the board 591 may be coupled to an electronic package 500 by interconnects 592. While shown as solder balls, it is to be appreciated that any interconnect architecture may be used to couple the board 591 to the electronic package 500.

In an embodiment, the electronic package 500 may comprise a package substrate 505. The package substrate 505 may include a core 509 and buildup layers 508 above and below the core 509. The core 509 may be a glass core 509 or an organic core 509. In an embodiment, the buildup layers 508 may include buildup film or the like. In an embodiment, conductive routing (not shown) is provided on and through the package substrate 505.

In an embodiment, a pair of dies 530A and 530B are shown as being coupled to the package substrate 505. For example, FLIs 535 may couple the dies 530 to the package substrate 505. In some embodiments, a bridge 520 may be provided between the first die 530 and the second die 530B. The bridge 520 communicatively couples the first die 530A to the second die 530B.

In order to mitigate DEM, a pair of dummy bridges 560 may be provided outside of the first die 530A and the second die 530B. The dummy bridges 560 may be substantially similar to the bridge 520, with the exception of the dummy bridges 560 not including routing. In an embodiment, the dummy bridges 560 and the bridge 530 may be inserted in cavities 503 that are formed into a top surface of the package substrate 505.

In the illustrated embodiment, a pair of two dies 530A and 530B and a pair of two dummy bridges 560 are shown, similar to the embodiment shown in FIGS. 2A-2C. However, it is to be appreciated that embodiments may include any number of dies 530 and any number of dummy bridges 560 in order to mitigate DEM in the electronic system 590. For example, embodiments similar to those shown in FIG. 3A-3B or 4A-4B can be used in the electronic system 590.

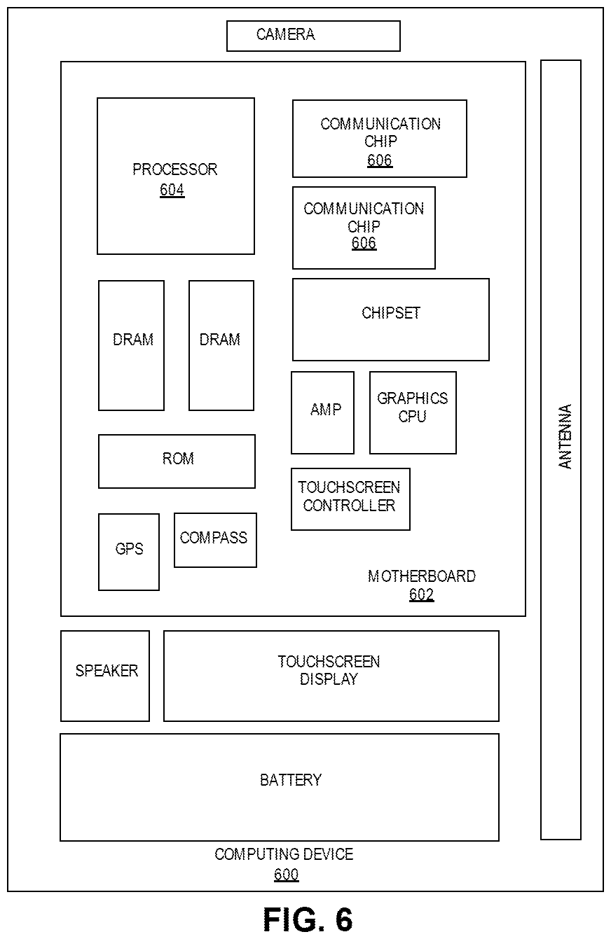

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic package that comprises a package substrate that includes one or more dummy bridge structures that are symmetrically disposed on the package substrate, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic package that comprises a package substrate that includes one or more dummy bridge structures that are symmetrically disposed on the package substrate, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package architecture, comprising: a package substrate; a first bridge over the package substrate, wherein the first bridge includes conductive routing; a second bridge over the package substrate; and a third bridge over the package substrate, wherein the second bridge and the third bridge are positioned symmetrically about the first bridge.

Example 2: the package architecture of Example 1, wherein the second bridge and the third bridge comprise silicon or glass.

Example 3: the package architecture of Example 1 or Example 2, wherein the second bridge and the third bridge comprise the same material as the first bridge.

Example 4: the package architecture of Examples 1-3, further comprising: a first die over the package substrate; and a second die over the package substrate, wherein the first die is communicatively coupled to the second die by the conductive routing in the first bridge.

Example 5: the package architecture of Example 4, wherein the second bridge and the third bridge are outside footprints of the first die and the second die.

Example 6: the package architecture of Examples 1-5, wherein the first bridge, the second bridge, and the third bridge are located in cavities in the package substrate.

Example 7: the package architecture of Examples 1-6, wherein a dimension of the first bridge is different than similar dimensions of the second bridge and the third bridge.

Example 8: an electronic package, comprising: a package substrate; a plurality of dies over the package substrate; a plurality of first bridges over the package substrate, wherein the plurality of first bridges are at least partially within footprints of the plurality of dies, and wherein the plurality of first bridges communicatively couple the plurality of dies together; and a plurality of second bridges over the package substrate, wherein the plurality of second bridges are entirely outside of footprints of the plurality of dies.

Example 9: the electronic package of Example 8, wherein the plurality of second bridges are dummy bridges.

Example 10: the electronic package of Example 9, wherein the dummy bridges do not include any conductive routing.

Example 11: the electronic package of Examples 8-10, wherein the plurality of second bridges comprise glass or silicon.

Example 12: the electronic package of Examples 8-11, wherein the plurality of second bridges are symmetrically oriented with respect to the plurality of dies.

Example 13: the electronic package of Examples 8-12, wherein the plurality of second bridges are along a first edge of the plurality of dies and a second edge of the plurality of dies.

Example 14: the electronic package of Example 13, wherein the first edge is opposite from the second edge.

Example 15: the electronic package of Examples 8-14, wherein the plurality of second bridges are along a first edge of the plurality of dies, a second edge of the plurality of dies, a third edge of the plurality of dies, and a fourth edge of the plurality of dies.

Example 16: the electronic package of Example 15, wherein a pair of second bridges are along each of the first edge, the second edge, the third edge, and the fourth edge of the plurality of dies.

Example 17: the electronic package of Examples 8-16, wherein the plurality of first bridges and the plurality of second bridges are positioned in cavities in the package substrate.

Example 18: the electronic package of Examples 8-17, wherein first level interconnect (FLI) structures between the plurality of dies and the package substrate are aligned with FLI pads on the package substrate.

Example 19: an electronic system, comprising: a board; a package substrate coupled to the board; a plurality of first bridges in the package substrate, wherein the plurality of first bridges comprise conductive routing; a plurality of second bridges in the package substrate, wherein the plurality of second bridges are symmetrically positioned with respect to the plurality of first bridges; and a plurality of dies coupled to the package substrate, wherein the plurality of first bridges communicatively couple together the plurality of dies.

Example 20: the electronic system of Example 19, wherein the plurality of second bridges are outside a footprint of the plurality of dies.

What is claimed is:

1. A package architecture, comprising:
a package substrate;
a first bridge over the package substrate, wherein the first bridge includes conductive routing;
a second bridge over the package substrate; and
a third bridge over the package substrate, wherein the second bridge and the third bridge are positioned symmetrically about the first bridge.

2. The package architecture of claim 1, wherein the second bridge and the third bridge comprise silicon or glass.

3. The package architecture of claim 1, wherein the second bridge and the third bridge comprise the same material as the first bridge.

4. The package architecture of claim 1, further comprising:
a first die over the package substrate; and
a second die over the package substrate, wherein the first die is communicatively coupled to the second die by the conductive routing in the first bridge.

5. The package architecture of claim 6, wherein the second bridge and the third bridge are outside footprints of the first die and the second die.

6. The package architecture of claim 1, wherein the first bridge, the second bridge, and the third bridge are located in cavities in the package substrate.

7. The package architecture of claim 1, wherein a dimension of the first bridge is different than similar dimensions of the second bridge and the third bridge.

8. An electronic package, comprising:
a package substrate;
a plurality of dies over the package substrate;
a plurality of first bridges over the package substrate, wherein the plurality of first bridges are at least partially within footprints of the plurality of dies, and wherein the plurality of first bridges communicatively couple the plurality of dies together; and
a plurality of second bridges over the package substrate, wherein the plurality of second bridges are entirely outside of footprints of the plurality of dies.

9. The electronic package of claim 8 wherein the plurality of second bridges are dummy bridges.

10. The electronic package of claim 9, wherein the dummy bridges do not include any conductive routing.

11. The electronic package of claim 8, wherein the plurality of second bridges comprise glass or silicon.

12. The electronic package of claim 8, wherein the plurality of second bridges are symmetrically oriented with respect to the plurality of dies.

13. The electronic package of claim 8, wherein the plurality of second bridges are along a first edge of the plurality of dies and a second edge of the plurality of dies.

14. The electronic package of claim 13, wherein the first edge is opposite from the second edge.

15. The electronic package of claim 8, wherein the plurality of second bridges are along a first edge of the plurality of dies, a second edge of the plurality of dies, a third edge of the plurality of dies, and a fourth edge of the plurality of dies.

16. The electronic package of claim 15, wherein a pair of second bridges are along each of the first edge, the second edge, the third edge, and the fourth edge of the plurality of dies.

17. The electronic package of claim 8, wherein the plurality of first bridges and the plurality of second bridges are positioned in cavities in the package substrate.

18. The electronic package of claim 8, wherein first level interconnect (FLI) structures between the plurality of dies and the package substrate are aligned with FLI pads on the package substrate.

19. An electronic system, comprising:
a board;
a package substrate coupled to the board;
a plurality of first bridges in the package substrate, wherein the plurality of first bridges comprise conductive routing;
a plurality of second bridges in the package substrate, wherein the plurality of second bridges are symmetrically positioned with respect to the plurality of first bridges; and
a plurality of dies coupled to the package substrate, wherein the plurality of first bridges communicatively couple together the plurality of dies.

20. The electronic system of claim 19, wherein the plurality of second bridges are outside a footprint of the plurality of dies.
